(19) United States
(12) Patent Application Publication
(10) Pub. No.: US 2025/0174256 A1
(43) Pub. Date: May 29, 2025

(54) CONFIGURATION MEMORY CELL

(71) Applicant: Microsemi SoC Corp, Chandler, AZ (US)

(72) Inventors: Victor Nguyen, San Ramon, CA (US); Fethi Dhaoui, Mountain House, CA (US); John L. McCollum, Orem, UT (US); Esmat Z. Hamdy, Fremont, CA (US)

(21) Appl. No.: 18/962,961

(22) Filed: Nov. 27, 2024

Related U.S. Application Data
(60) Provisional application No. 63/603,988, filed on Nov. 29, 2023.

(51) Int. Cl. G11C 7/10; G11C 7/12

(52) U.S. Cl. CPC G11C 7/1096; G11C 7/12

(57) ABSTRACT

An apparatus may include a configuration memory cell. The configuration memory cell may include a first connection point to control access of one or more storage nodes of the configuration memory cell; a second connection point to manage stability of one or more storage nodes of the configuration memory cell during access of the configuration memory cell; and a third connection point to control voltage transitions at one or more of the storage nodes of the configuration memory cell during access of the configuration memory cell.

### CROSS-REFERENCE

This application claims the benefit of the filing date of U.S. Provisional Patent Application Ser. No. 63/603,988, filed Nov. 29, 2023, for “CONFIGURATION MEMORY CELL,” the disclosure of which is hereby incorporated herein in its entirety by this reference.

### FIELD

One or more examples relate, generally, to a configuration memory cell. One or more examples relate to additional NMOS transistors in the bit line (BL) path—as compared to traditional configuration memory cells utilized in FPGAs—that enable more reliable cell write operations under both BL high and low conditions.

### BACKGROUND

Storage elements (e.g., volatile storage elements, without limitation) are utilized in a variety of operational context.

### BRIEF DESCRIPTION OF THE DRAWINGS

To easily identify the discussion of any particular element or act, the most significant digit or digits in a reference number refer to the figure number in which that element is first introduced.

FIG. 1 is a schematic diagram depicting the layout of a configuration memory cell designed to provide Single Event Upset (SEU) immunity while operating reliably in a high-voltage (HV) domain, in accordance with one or more examples.

FIG. 2 is a block diagram depicting a memory system that includes a configuration memory cell and its associated driver circuitry, in accordance with one or more examples.

FIG. 3 is a voltage bias and state table depicting operation states of a configuration memory cell or system, in accordance with one or more examples.

FIG. 4 is a flow diagram depicting a process to control a configuration memory cell during an access operation, in accordance with one or more examples.

FIG. 5 is a flow diagram depicting an example process for a two-phase write ‘0’ to an example configuration memory cell, in accordance with one or more examples.

FIG. 6 is a flow diagram depicting an example process for a two-phase write ‘1’ to an example memory cell, in accordance with one or more examples.

FIG. 7 is a flow diagram depicting an example process for a two-phase read ‘0’ from an example configuration memory cell, in accordance with one or more examples.

FIG. 8 is a flow diagram depicting an example process for a two-phase read ‘1’ from an example configuration memory cell, in accordance with one or more examples.

FIG. 9 is a block diagram of circuitry that, in some examples, may be used to implement various functions, operations, acts, processes, or methods disclosed herein.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments may be utilized, and structural, material, and process changes may be made without departing from the scope of the disclosure.

The illustrations presented herein are not meant to be actual views of any particular method, system, device, or structure, but are merely idealized representations that are employed to describe the embodiments of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawing could be arranged and designed in a wide variety of different configurations. Thus, the following description of various embodiments is not intended to limit the scope of the present disclosure, but is merely representative of various embodiments. While the various aspects of the embodiments may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the embodiments disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer executes computing instructions (e.g., software code) related to embodiments of the present disclosure.

The embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, any relational term, such as “over,” “under,” “on,” “underlying,” “upper,” “lower,” without limitation, is used for clarity and convenience in understanding the disclosure and accompanying drawings and does not connote or depend on any specific preference, orientation, or order, except where the context clearly indicates otherwise.

In this description the term “coupled” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The term “connected” may be used in this description interchangeably with the term “coupled,” and has the same meaning unless expressly indicated otherwise or the context would indicate otherwise to a person having ordinary skill in the art.

As used herein, the terms “assert,” “de-assert” and derivatives thereof used in reference to a pin, means, respectively, to assert or de-assert a signal associated with the pin (e.g., a signal specifically assigned to the pin or a signal to which the pin is specifically assigned, without limitation).

A “volatile storage cell” is a type of data storage that requires continuous power to maintain the information stored within it. A volatile storage cell represents information via its state (e.g., charged, or uncharged, high voltage or low voltage, without limitation) and it requires continuous power to keep its state. If the power supply to the cell is interrupted or turned off, the volatile storage cell loses state and the information stored in the volatile storage cell is lost.

Examples of volatile storage cells include, but are not limited to: latch circuits, flip-flop circuits, and circuits including cross-coupled inverters. Some field-programmable gate arrays (FPGAs) include configuration memory cells that include volatile storage cells. Further, static random-access memory (SRAM) cells include volatile storage cells.

The terms “memory cell” and “volatile storage cell” are used interchangeable herein to mean a “volatile storage cell.” When utilized in an FPGA, an example memory cell discussed herein may be referred to as a “configuration memory cell” or just a “configuration memory cell.”

Traditional configuration memory cells utilized in FPGAs cannot perform read or write operations (are unable to be written to or read from) when powered up in a high-voltage domain (voltage conditions higher than a positive supply voltage) due to transistor stress limitations and specific internal connections of transistors. In some implementations, a traditional configuration memory cell powered by a high voltage power source is powered down, powered up with a lower voltage supply, various access operations are performed in the lower voltage domain, powered down again, and then powered up again with the higher voltage supply. The powering down and powering up consumes power and reduces performance. Here, “positive supply voltage” refers to the standard positive supply voltage (e.g., VDD, without limitation) used to represent standard logic high level (logic ‘1’) for low voltage components. Non-limiting examples of voltage levels of VDD include 1.2V logic, 1.8V logic, 2.5V logic, 3.3V logic, and 5V logic.

By way of non-limiting example, an FPGA may use VDD of 1.2V for standard logic level of low-voltage components, and a positive high voltage (VPHV) of 9V for programming or configuration operations.

One or more examples relate, generally, to a configuration memory cell, and FPGA including the same. The configuration memory cell is designed to withstand Single Event Upsets (SEUs) in high-voltage (HV) environments (“SEU immunity”). More specifically, the configuration memory cell may include a High Resistance Element (HRE) for SEU immunity. Non-limiting examples of an HRE include various physical configurations: capacitors with layered dielectrics, high-impedance resistors, transistors configured for high resistance, and multi-layer dielectric structures.

One or more examples relate, generally, to including additional NMOS transistors in the bit line (BL) path—as compared to traditional configuration memory cells utilized in FPGAs. The NMOS transistors enable more reliable cell write operations under both BL high and low conditions.

In one or more examples, a configuration memory cell may include a word line (WL) (which may be an additional word line as compared to traditional configuration memory cells utilized in FPGAs) to enable the configuration memory cell to be written and read while under high voltage without exposing any single device to excessive stress that could cause SEU. Notably, this avoids ramping down VPHV (high voltage supply) during write operations and disruption to logic systems associated with the same.

In one or more examples, biasing through dedicated word lines (e.g., WL2 and WL3) allows precise control during writes, ensuring the correct state is set while maintaining robustness.

Various examples support multiple latch structures, such as cross-coupled inverters, NAND/NOR gates, or SRAM cells with variations such as stacked or separate supply domains.

Various examples support both single and multiple bit lines and word lines, offering flexibility in FPGA integration.

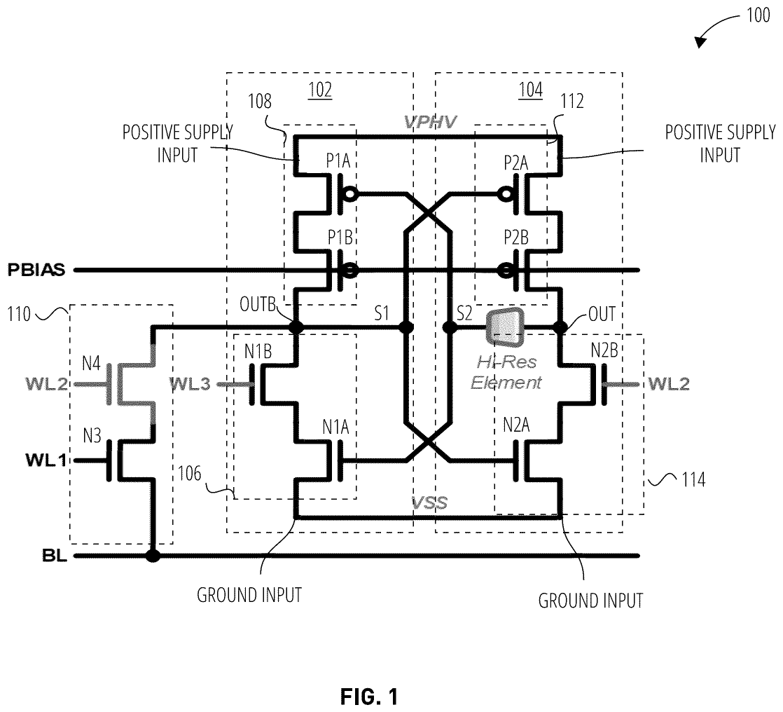

FIG. 1 is a schematic diagram depicting the layout of a configuration memory cell 100 designed to provide Single Event Upset (SEU) immunity while operating reliably in a high-voltage (HV) domain, in accordance with one or more examples. Configuration memory cell 100 includes PMOS and NMOS transistors arranged in a configuration that defines the cell's state.

Specifically, configuration memory cell 100 includes a pair of cross-coupled inverters, first inverter 102 and second inverter 104, with the respective output of each inverter coupled (e.g., electrically coupled, without limitation) to respective inputs of the other inverter. Notably, in a case where the signal state of configuration memory cell 100 is configuration data (e.g., data the value of which determines the behavior of an FPGA's logic elements, without limitation), a signal on output OUT may carry the stored configuration data from configuration memory cell 100. Configuration memory cell 100 has two stable states, here, logic low ‘0’ and logic high ‘1.’ The cross-coupled inverters are the state retaining element of configuration memory cell 100. The cross-coupled inverters first inverter 102 and second inverter 104 form a configuration that allows configuration memory cell 100 to define and maintain a stable state during operation. This configuration enables configuration memory cell 100 to hold either a logic ‘0’ or logic ‘1’ depending on input signals.

The state of configuration memory cell 100 is stored at the storage nodes S1 and S2, which use voltage values corresponding to VPHV and VSS to store signal state of configuration memory cell 100. The cross-coupling configuration of first inverter 102 and second inverter 104 reinforce the voltage levels at nodes S1 and S2 to ensure that the cell maintains a stable state.

Respective positive voltage supply inputs of both of first inverter 102 and second inverter 104 are coupled to a first voltage supply VPHV and respective ground inputs of both inverters are coupled to a second voltage supply VSS. VPHV is utilized to represent a logic high signal state (a logic ‘1’), and VSS is utilized to represent the logic low signal state (a logic ‘0’0) within configuration memory cell 100. The respective inputs for receiving the first supply voltage VPHV are operable to be coupled solely to the first voltage supply. In one or more examples, the respective inputs for receiving first supply voltage VPHV are directly coupled to the voltage supply, with no intervening elements that could switch the supply to a lower voltage level.

First inverter 102 includes two PMOS transistors P1A and P1B connected in series, and two NMOS transistors N1A and N1B connected in series. Similarly, second inverter 104 includes two PMOS transistors P2A and P2B connected in series, and two NMOS transistors N2A and N2B connected in series. PMOS transistors P1A, P1B of first inverter 102 and P2A, P2B of second inverter 104 respectively act as a pull-up network.

NMOS transistors N1B and N2B are controlled by word lines WL3 and WL2, respectively. When NMOS transistors N1B and N2B are ON, NMOS transistor N1A, N1B of first inverter 102 and NMOS transistors N2A, N2B of second inverter 104 respectively act as a pull-down network, as discussed below.

In first inverter 102 and second inverter 104, the sources of N1A and N2A are connected to a voltage supply line, VSS, which is associated with a logic low level (0V), and the drains of N1A and N2A are connected to the sources of NMOS transistors N1B and N2B. The drain of N1B is connected to node S1 and OUTB, and the drain of N2B is connected to OUT and connected to node S2 via Hi-Res Element.

In first inverter 102 and second inverter 104, the sources of P1A and P2A are connected to the first voltage supply line VPHV, associated with a logic high level. The drains of P1A and P2A are connected to the sources of PMOS transistors P1B and P2B, respectively. The drain of P1B is connected to OUTB and node S1. The drain of P2B is connected to OUT and connected to node S2 via Hi-Res Element.

Single instances of PMOS transistors P1A, P1B, P2A, and P2B are depicted, and single instances of NMOS transistors N1A, N1B, N2A and N2B are depicted in FIG. 1. The number of NMOS and PMOS transistors used in the cross-coupled inverters first inverter 102 and second inverter 104 may be chosen to balance performance, area, and power consumption. In the case of one or more of PMOS transistors P1A, P1B, P2A, and P2B or NMOS transistors N1A, N1B, N2A and N2B, multiple transistors may be present in a stacked configuration. In a stacked configuration, the transistors are arranged such that the drain of one transistor is connected to the source of another. This stacking allows for a division of voltage across the transistors, helping to manage the voltage stress within the devices (e.g., ensuring voltage across terminal nodes of the transistors are within tolerances, without limitation), including during access operations discussed herein (e.g., read, and two-phase write operations, discussed herein, without limitation).

### Access Device & Drive Control Transistor

Output OUTB is connected to access device 110, which is controlled by word lines WL1 and WL2, respectively. Access device 110 selectively transfers the signal state between storage node S1 of configuration memory cell 100 and the bit line (BL). During a write operation, access device 110 allows transfer of signal state from the bit line BL to configuration memory cell 100 (or more specifically storage node S1). During a read operation, the access device 110 allows transfer of signal state from configuration memory cell 100 (or, more specifically, storage node S1) to the bit line BL.

Configuration memory cell 100 may optionally include a high resistance element (optional “Hi Res Element”). The Hi-Res Element is an element (e.g., a material, a structure, device, circuit, or combinations/subcombinations thereof, without limitation) characterized by a resistance to an inducement of a flow of charge therethrough suitable to change in a state of configuration memory cell 100.

### Pull-Up and Pull-Down Networks of First Inverter 102

Pull-down network 106 acts to at least partially set a voltage level at output OUTB and node S1 to VSS as discussed herein. Pull-up network 108 acts to set a voltage level at output OUTB and node S1 to VPHV as discussed herein.

Pull-down network 106 has an NMOS cascode structure. Specifically, pull-down network 106 includes NMOS transistors N1A and N1B arranged as a cascode voltage switch (pull-down network 106 may also be referred to as “cascode voltage switch 106”) that acts as a switch to VSS when the cascode voltage switch is ON.

NMOS transistor N1B provide fine control over the state of storage node S1/OUTB during write and read operations. By modulating WL3, NMOS transistor N1B adjusts how strongly the storage node S1/OUTB is driven to ensure smoother transitions and improved write and read margins, as discussed below. NMOS transistor N1B may also be referred to herein as “fine control transistor N1B.”

Fine control transistor N1B provides stabilization and precise control over the voltage transition of S1/OUTB during read and write operations, for example, by modulating current flow to/from storage node S1/OUTB. When NMOS transistor N1B is ON (e.g., WL3 is activated/set to a voltage such as 1.1V), NMOS transistor N1B creates an additional pathway to the VSS supply line that helps stabilize the voltage at S1/OUTB. NMOS transistor N1B provides an additional control path when WL3 is activated. Control of voltage transitions may include control of the states the voltage stops at during a transition (e.g., beginning state, end state, intermediate states, without limitation), control of the time it takes to perform a voltage transition or intermediate transitions (e.g., rise times, fall times, signal propagation times, without limitation), and control of the stability of a voltage transition (e.g., one or more of: smoothing voltage changes to prevent overshoot or undershoot, maintaining consistent rise and fall times, minimizing noise-induced fluctuations, or ensuring a predictable settling time, without limitation).

This precision helps ensure that the voltage at S1/OUTB reaches its target level (e.g., either VPHV or 0V) effectively, without overshoot or undershoot. By reducing the likelihood of incorrect or incomplete state transitions, NMOS transistor N1B enhances the ability to reliably write the desired logic level into the memory cell. NMOS transistor N1B may also be referred to herein as a “stabilization transistor N1B.”

Pull-up network 108 has a PMOS cascode structure. Specifically, pull-up network 108 includes transistors P1A and P1B arranged as a cascode voltage switch (so pull-up network 108 may also be referred to as “cascode voltage switch 108”) that acts as a switch to VPHV when the cascode voltage switch 108 is ON.

Transistor N1A of pull-down network 114 and transistor P1A of the pull-up network 112 are in a common gate configuration (their respective gates are coupled). An internal node between respective gates of N1A and P1A is utilized as the input of first inverter 102.

Stabilization transistor N1B of pull-down network 106 and transistor P1B of the pull-up network 108 are in a common gate configuration (respective gates are coupled). An internal node between respective gates of stabilization transistor N1B and transistor P1B is utilized as the input of first inverter 102.

### Pull-Up and Pull-Down Networks of Second Inverter 104

Pull-down network 114 acts to at least partially set a voltage level at output OUT and node S2 to VSS as discussed herein. Pull-up network 112 acts to set a voltage level at output OUT and node S2 to VPHV as discussed herein.

Pull-down network 114 has an NMOS cascode structure. Specifically, pull-down network 114 includes N2B and N2A arranged as a cascode voltage switch (so pull-down network 114 may also be referred to as “cascode voltage switch 114”) that acts as a switch to VSS when the cascode voltage switch 114 is ON. N2A acts as a transconductance voltage amplifier. NMOS transistor N2B acts as a buffer/voltage protection device for NMOS transistor N2A as discussed herein. Specifically, NMOS transistor N2B acts as a buffer/voltage protection between output OUT and N2A. NMOS transistor N2B may also be referred to herein as a “stabilization transistor N2B.”

In one or more examples, protection offered by NMOS transistors N2B and N1B may be different and separately controllable via different signals, such as signals WL3 and WL2, without limitation. In one or more examples, configuration memory cell 100 or a device or circuit including the same, may include respective connection points for receiving respective ones of signals WL1, WL2 or WL3. As a non-limiting example, configuration memory cell 100 or a device or circuit including the same may include respective connection points (e.g., a logical and/or physical interface, such as a pad, or terminal, without limitation that facilitates signal exchange between components) to receive signals WL1, WL2, and WL3 and route the signals to corresponding control points (nodes or terminals where signals are applied to influence (e.g., control, without limitation) the operation or behavior of the configuration memory cell 100 or its respective components or subsystems) of the configuration memory cell 100.

Pull-up network 112 has a PMOS cascode structure. Specifically, pull-up network 112 includes P2A and P2B arranged as a cascode voltage switch (so pull-up network 108 may also be referred to as “cascode voltage switch 112”) that acts as a switch to VPHV when the cascode voltage switch 112 is ON.

NMOS transistor N2A of pull-down network 114 and P2A of the pull-up network 112 are in a common gate configuration (their respective gates are coupled). An internal node between respective gates of N2A and P2A is utilized as the input of second inverter 104.

Transistor N2B of pull-down network 114 and P2B of pull-up network 112 are in a common source configuration (respective sources are coupled). An internal node between respective sources of N2B and P2B is utilized as the output OUTB of second inverter 104.

### Optional Hi-Res Element

The terms “single event upset” and “SEU” refer to a change in state of the source node or drain node of a transistor resulting from one or more ionizing particles affecting the transistor. For example, a source node or drain node of a transistor may be struck by a heavy ion which may cause an influx of electron-hole pairs which may drive the source node or drain node higher or lower in voltage. The higher or lower voltage at the source node or drain node of the transistor may result in a change in a state (e.g., “on” to “off” or “off” to “on”) of the transistor. The term SEU may be applied to a transistor to indicate that the transistor has changed state based on an SEU. The term SEU may also be applied to a device (e.g., a volatile storage element, without limitation) to indicate that the device has changed state based on an SEU, for example, a bit of data stored by the volatile storage element may change as a result of the SEU.

The terms “single-event-upset resistant,” or “SEU resistant,” may refer to a state of being more resistant to SEU than another system, circuit, or device. In particular, an SEU-resistant system, circuit, or device may include one or more elements that may allow the SEU-resistant system, circuit, or device to be less likely to experience an SEU than systems, circuits, or devices that do not include the one or more elements.

Additionally or alternatively, SEU resistance may improve a system, circuit, or device by making the system, circuit, or device more resistant to events that may disturb a state of a latch of the system, circuit, or device. For example, SEU resistance may improve how a system, circuit, or device responds to an event that enables a word line for a short period of time. Examples of events that may enable a word line for a short period of time include user error or a bug in a control system that drives a word line without limitation.

In general, volatile storage elements may be affected by SEUs. As a non-limiting example, a transistor node of an inverter of a pair of cross-coupled inverters of a volatile storage element may change states in response to an SEU, and as a result, a bit of data stored by the volatile storage element may change.

Configuration memory cell 100 may include one or more optional High Resistance Elements (“Hi-Res Element”) in a circuit, specifically in paths that include components vulnerable to SEUs. For instance, adding a Hi-Res Element in the loop between cross-coupled inverters increases the circuit's time constant (e.g., RC time). This increased time constant makes the circuit less susceptible to SEUs, which are typically short-duration events. An SEU might cause a rapid voltage change that could change (e.g., flip) the state of cross-coupled inverters. The Hi-Res Element resists rapid voltage changes across the transistors, helping the inverters maintain or revert to their pre-SEU state before the incorrect state is fully established. A Hi-Res Element, characterized by its suitable resistance to charge flow that could alter the state of the volatile storage device, can include components such as: resistive random-access memory (ReRAM), an anti-fuse, a vertical resistor, a capacitor between two conductive or semi-conductive materials made of one or more element layers with the dielectric region consisting of a single or multiple layers of dielectric or semi-dielectric material, a transistor coupled to behave as a high impedance element (the transistor may be a thin-film device), a high impedance resistor, a device having a dielectric between same metal layer including metal gates and contact layers, or a device having multiple dielectric layers across multiple metal layers including metal gates and contact layers.

In one or more examples, inclusion of Hi-Res Element in a path of a loop between cross-coupled inverters (e.g., first inverter 102 and second inverter 104) may set a higher time constant of a circuit that includes the Hi-Res Element as compared to a circuit that does not include Hi-Res Element. Such a higher time constant may set a higher resistance to changes to the state of cross-coupling nodes S1 and S2 (and configuration memory cell 100 more generally and as compared to a circuit that does not include a Hi-Res Element) caused by relatively short duration events. Accordingly, Hi-Res Element stabilizes the state of configuration memory cell 100.

Hi-Res Element may resist changes due to wanted events (e.g., write pulses, without limitation) and unwanted events (e.g., a single event upset (SEU), without limitation). Since a Hi-Res Element may resist change in state in response to a write pulse, longer write pulses may be utilized in instances where a Hi-Res Element is present than in instances where a Hi-Res Element is not present.

In one or more examples, Hi-Res Element may be coupled on the left side (first inverter 102), right side (second inverter 104, as depicted by FIG. 1), or both sides of the latch structure (a Hi-Res Element coupled at first inverter 102, a further Hi-Res Element coupled at second inverter 104). In one or more examples, multiple Hi-Res elements of the same or different types may be coupled in series, in parallel, or in any other suitable circuit topology. A Hi-Res Element may be coupled with (or may provide coupling between) output of one or more Inverter/NAND/NOR gate implementations to input of one or more Inverter/NAND/NOR gate implementations.

As noted, above, Hi-Res Elements are optional and not required. For example, a configuration memory cell 100 without a Hi-Res Element might be suitable for operating conditions where SEU is not expected or addressed differently.

### WL1 & WL2

Access device 110 is controlled by word lines WL1 and WL2. WL1 and WL2 are received at the gates of access transistor N3 and drive control transistor N4 of access device 110, respectively. When both of access transistor N3 and drive control transistor N4 are ON, it connects bit line BL to storage node S1/OUTB and allows the bit line BL to influence the state of storage node S1/OUTB (for write operations) or allows the state of storage node S1/OUTB to be sensed on the bit line BL (for read operations).

Stabilization transistor N2B of second inverter 104 is also controlled by word line WL2. When ON, stabilization transistor N2B creates at least a portion of a selective path to ground (VSS) through the series connection with N2A. Stabilization transistor N2B stabilizes the storage node S2/OUT by providing a controlled discharge path to VSS when activated by WL2. As discussed, below, the modulation of WL2 determines how effectively stabilization transistor N2B pulls storage node S2/OUT to ground (VSS), stabilizing the complementary state of the cross-coupled inverters during both read and write operations.

WL2 controls the gate voltage of both stabilization transistor N2B and drive control transistor N4. By modulating the level of WL2, the gate-to-source voltage (Vgs) of transistors N4 and N2B are adjusted, which in turn sets their active drive strength. A higher WL2 voltage (beyond the threshold voltage, Vth) increases the drive strength, allowing more current to flow. Conversely, lowering WL2 reduces the drive strength, limiting current flow.

“Active drive strength” refers to a characterization or measure of how strongly a transistor may drive a current through a load when it is turned ON. In the case of Field Effect Transistors (FETs) such as MOSFETS (Metal-Oxide-Semiconductor Field-Effect Transistors) or FinFETs (Fin Field-Effect Transistors), increasing the gate-to-source voltage (Vgs) beyond the threshold voltage (Vth) enhances the channel conductivity, thereby increasing the drive strength, up to a point where additional increases have diminishing returns. In one or more examples, modulations levels of signal WL2 may be utilized to set Vgs of access transistor N4 and N2B.

As used herein, “write margin” refers to a characterization or measure of the ease with which the state of configuration memory cell 100 may be changed. So, “increasing” write margin of configuration memory cell 100 means making it easier to change the state of configuration memory cell 100.

Active drive strength of drive control transistor N4 and stabilization transistor N2B determines how strongly drive control transistor N4 and stabilization transistor N2B can “pull” their respective nodes, for example, drive control transistor N4 pulls S1/OUTB toward BL during access, and stabilization transistor N2B pulls S2/OUT toward VSS for stabilization. Thus, in the case of a write, WL2 modulation can make it easier or harder to change the state of the memory cell during a write operation by adjusting how effectively the drive control transistor N4 and stabilization transistor N2B drive current into or away from the storage nodes. Further, in the case of a read, WL2 modulation helps ensure that the state of the configuration memory cell can be read reliably without disturbing the stability of the configuration memory cell's stored state (e.g., avoiding accidental state flips from disturbances caused by read operations, without limitation).

The active drive strength also affects power consumption. Higher drive strength (with increased WL2 levels) leads to stronger current flow but higher power dissipation. Lower drive strength reduces power consumption but might compromise margin reliability. Adjustable WL2 levels enables fine-tuning of the configuration memory cell's performance for different operating conditions: High WL2 voltage: Increases write/read margin at the cost of higher power consumption, Lower WL2 voltage: Reduces power consumption but may slightly degrade margins. Acceptable trade-offs between power consumption and write margin may be determined, as a non-limiting example, based on specific operating conditions.

Accordingly, WL2 provides a single signal to modulate the gate voltages of both drive control transistor N4 and stabilization transistor N2B. In the case drive control transistor N4, WL2 controls how strongly the bit line (BL) influences the storage node S1/OUTB based on the active dive strength setting of drive control transistor N4. In the case of stabilization transistor N2B, WL2 controls how effectively the storage node S2/OUT is stabilized by providing a discharge path to VSS.

### WL3

As mentioned above, fine control transistor N1B provide fine control over the state of storage node S1/OUTB during write and read operations. By modulating WL3, fine control transistor N1B adjusts how strongly the storage node S1/OUTB is driven to ensure smoother transitions and improved write and read margins. The gate of fine control transistor N1B is connected to word line WL3. Modulation levels of signal WL3 set the state (ON or OFF) of N1B and active drive strength. When N1B is OFF, that increases write margin and read margin (relative to when N1B is ON) at configuration memory cell 100, and reduces power consumption.

### Signal PBIAS

The respective gates of P1B and P2B are connected to the PBIAS line, which supplies a bias voltage V_{PBIAS} (voltage not depicted). Transistors P1B and P2B are biased PMOS transistors. PBIAS sets the gate-source voltage of the PMOS transistors (here, P1B and P2B). By setting PBIAS at an appropriate level, the gate-source voltage (Vgs) of the PMOS transistors is managed such that the transistors operate within their safe region. While PBIAS directly controls Vgs, it indirectly controls Vds by ensuring that respective PMOS transistors stay in a region where the drain-source voltage does not exceed the tolerance. PBIAS can ensure that the drain of P1B or P2B does not rise too high relative to the source, keeping Vds within tolerance limits. So, the PBIAS line effectively conditions P1B and P2B so that their respective drain voltages V_{D} are constrained to be a fraction of their respective source voltages VS, limiting the voltage stress across them.

In one or more examples, the bias levels of bias voltage PBIAS applied to gates of PMOS transistors, and the set of respective PMOS transistors to which PBIAS voltages are applied, is chosen to ensure that the drain-source voltages remain within limits (e.g., limits at least partially defined by specific voltage tolerances across specific nodes of the transistor, which may be non-uniform, without limitation), including for operation of configuration memory cell 100 in a high voltage domain VPHV. In one or more examples, the amount of bias may be chosen to provide sufficient gate control while reducing the impact of voltage stress on the transistors. This ensures that the transistors operate reliably without exceeding respective voltage tolerances.

In one or more examples, The voltage tolerances of the transistors, particularly their drain-source (Vds) limits, may be considered in the design of a configuration memory cell 100. PMOS and NMOS transistors in the configuration memory cell 100 are partially voltage tolerant, and so can withstand higher Vgs and Vgd voltages, but their Vds must be kept below a certain threshold (e.g., 1.2V) that is lower than the threshold that may be tolerated for Vgs and Vg.

As noted above, various designs contemplated herein ensure respective tolerances are met (e.g., not exceeded, without limitation), at least in part, by distributing the voltage across multiple transistors (e.g., in stacked configurations, without limitation) and by careful biasing.

In one or more examples, one or more parameters—transistor count, bias voltages, and voltage tolerances—may be pre-determined during a design phase to ensures that the configuration memory cell 100 meets various specifications for read and write operations, including two-phase read and write operations, and resistance to SEUs. Process variation and operational conditions also may be considered during optimization to ensure the design performs consistently across different manufacturing batches and in various operating environments.

PMOS transistor P1B and PMOS transistor P2B may optionally be coupled to receive signal PBIAS. Modulation levels of signal PBIAS may be utilized to increase or decrease bias conditions at PMOS transistor P1B and PMOS transistor P2B based on specific operating conditions, as discussed below.

### Modes and Features Set via Signals WL2, WL3 and PBIAS

Modulation levels of signals WL2, WL3 and PBIAS may be utilized to set various, distinct modes or features at configuration memory cell 100, such as a write assist (a bias condition is weakened for a limited time duration to increase write margin), and reduced read disturbance (a bias condition is strengthened for a limited time duration to reduce read disturbance and thereby increase read margin).

### Nonuniform Voltage Tolerance

One or more of NMOS access transistor N3, drive control transistor N4, PMOS transistors P1A, P1B, P2A, and P2B, and NMOS transistors N1A, N1B, N2A, and N2B may exhibit nonuniform voltage tolerance. A nonuniform voltage tolerant transistor can tolerate different voltage levels across its different terminals (e.g., gate-drain (Vgd), gate-source (Vgs), drain-source (Vds)). In one or more examples, such a transistor may handle higher voltages across Vgs and Vgd and have lower voltage tolerance across Vds. If the Vds voltage exceeds the tolerance threshold (what a transistor can tolerate for more than a negligible amount of time), the transistor may suffer damage over time, leading to potential breakdown, short circuits, or leakage current.

Here, access transistor N3, drive control transistor N4, PMOS transistors P1A, P1B, P2A, and P2B, and NMOS transistors N1A, N1B, N2A, and stabilization transistor N2B are not high-voltage tolerant across their drain-source nodes. These transistors can tolerate voltages across their drain-source nodes up to VDD, but not above (e.g., could not tolerate VPHV). These transistors can tolerate voltages at least up to VPHV, and optionally beyond, across their gate-drain nodes and their gate-source nodes.

### Leakage Control in Programmable Switch of a Switching Matrix of an FPGA

In the FPGA version, the configuration memory cell 100 and a pass-gate (e.g., a transistor, without limitation) form a programmable switch. The output of the configuration memory cell drives the pass-gate, which provides the connection. The programmable switch is connected when the pass-gate is ON, and unconnected with the pass-gate is OFF.

Over-drive the gate of the pass-gate to use with a 1.8V supply voltage.

When this configuration memory cell produces 1.8V at its output and conditions the pass-gate to be ON, it exhibits reliable over-drive from passing signals that are at logic level, which is typically 0.9V or below.

Bias-modulation of the PMOS transistors driven by PBIAS and the NMOS transistors driven by WL2 & WL3 with partially voltage tolerant transistors suppresses gate leakage.

Bias-modulation of the PMOS transistors driven by PBIAS and the NMOS transistors driven by WL2 & WL3 and cascode arrangement (additionally or alternatively to gate leakage) suppresses other types of leakage.

### Other Power Domains

Notably, configuration memory cell 100 is designed to support coupling to alternative voltage supplies in place of one or both of VPHV and VSS, depending on the specific operating conditions (e.g., application requirements, without limitation). For example, configuration memory cell 100 may be coupled to a VDD power supply in lieu of the VPHV high-voltage supply.

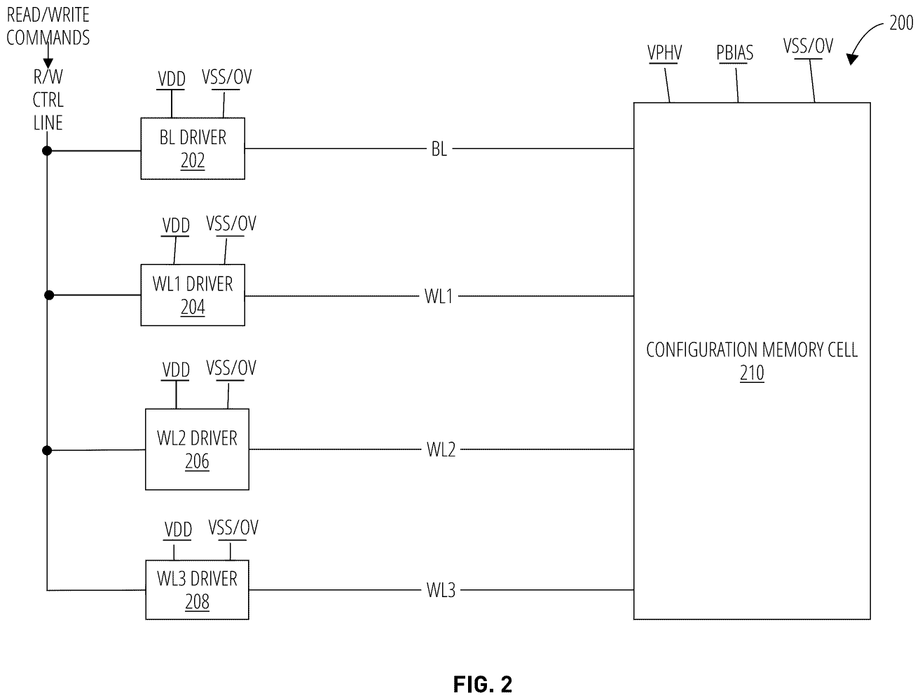

FIG. 2 is a block diagram depicting a memory system 200 that includes a configuration memory cell 210 and its associated driver circuitry, in accordance with one or more examples. This system is designed to manage high-voltage operations and low-voltage control signals for read and write operations.

Memory system 200 includes BL driver 202, WL1 driver 204, WL2 driver 206, WL3 driver 208 and configuration memory cell 210.

Configuration memory cell 210 is a configuration memory cell that operates in a high-voltage (HV) domain in accordance with examples discussed herein, such as configuration memory cell 100, without limitation. Configuration memory cell 210 is connected to both high-voltage (VPHV) and low-voltage (VSS/0V) supplies. Further, Configuration memory cell 210 is connected to supplies for a PBIAS voltage discussed above. Furthermore, configuration memory cell 210 is connected to BL driver 202, WL1 driver 204, WL2 driver 206, and WL3 driver 208, by BL, WL1, WL2, and WL3, respectively.

VPHV is the high-voltage supply connected to configuration memory cell 210, ensuring that it can operate in a high-voltage domain. VSS/0V is a low-voltage (ground) supply connected to both configuration memory cell 210 and the drivers of associated driver circuitry (here, BL driver 202, WL1 driver 204, WL2 driver 206, and WL3 driver 208). The drivers may use VSS/0V as a reference voltage for their low-voltage operations.

BL driver 202 controls the bit line (BL), which interfaces with the configuration memory cell 210 for read and write (R/W) operations. The BL driver 202 is powered by VDD and VSS/0V, indicating that it operates in a low-voltage domain. The BL driver 202 receives read/write commands and generates appropriate signals to drive the bit line (BL), enabling data to be written to or read from configuration memory cell 210.

WL1 driver 204 controls (e.g., activates/deactivates, without limitation) the word line 1 (WL1), which is used to allow access to the configuration memory cell 210 during read and write operations. In the case of configuration memory cell 100 and access device 110, WL1 enables or disables the access transistor N3 of access device 110. Like the BL driver 202, the WL1 driver 204 is powered by VDD and VSS/0V, indicating it operates in the low-voltage domain. The WL1 driver 204 receives read/write commands and drives WL1 to control access to the configuration memory cell 210.

WL2 driver 206 controls (e.g., activates/deactivates, without limitation) the word line 2 (WL2), which, together with word line WL1, is used to allow access to the configuration memory cell 210 during read and write operations. In the case of configuration memory cell 100 and access device 110, WL2 enables or disables the drive control transistor N4 and stabilization transistor N2B. Further, modulation of WL2 sets the respective active drive strength of drive control transistor N4 and stabilization transistor N2B. Like the BL driver 202 and WL1 driver 204, the WL2 driver 206 is powered by VDD and VSS/0V, indicating it operates in the low-voltage domain. The WL2 driver 206 receives read/write commands and drives WL2 to control access to the configuration memory cell 210.

WL3 driver 208 controls (e.g., activates/deactivates, without limitation) the word line 3 (WL3), which provides additional control over one or both of the storage nodes S1 and S2 during read and write operations, for example, facilitating precise transitions during phases of read and write sequences as discussed below. WL3 driver 208 is powered by VDD and VSS/0V, indicating it operates in the low-voltage domain. WL3 enables or disables the fine control transistor N1B. Further, modulation of WL3 sets the active drive strength of fine control transistor N1B.

In one or more examples, WL3 driver 208, WL1 driver 204 and WL2 driver 206 act in coordination to ensure proper access to configuration memory cell 210 during access operations (e.g., read and write, without limitation).

Here, the term “activate” when used in connection with a word line means to apply a voltage to the word line that turns on the access transistors connected to it. Here, the term “deactivate” when used in connection with a word line means to apply a voltage (typically 0V or another appropriate level) to the word line that turns off the access transistors connected to it. Both an activated and a deactivated word line may be modulated to set active drive strength as discussed herein.

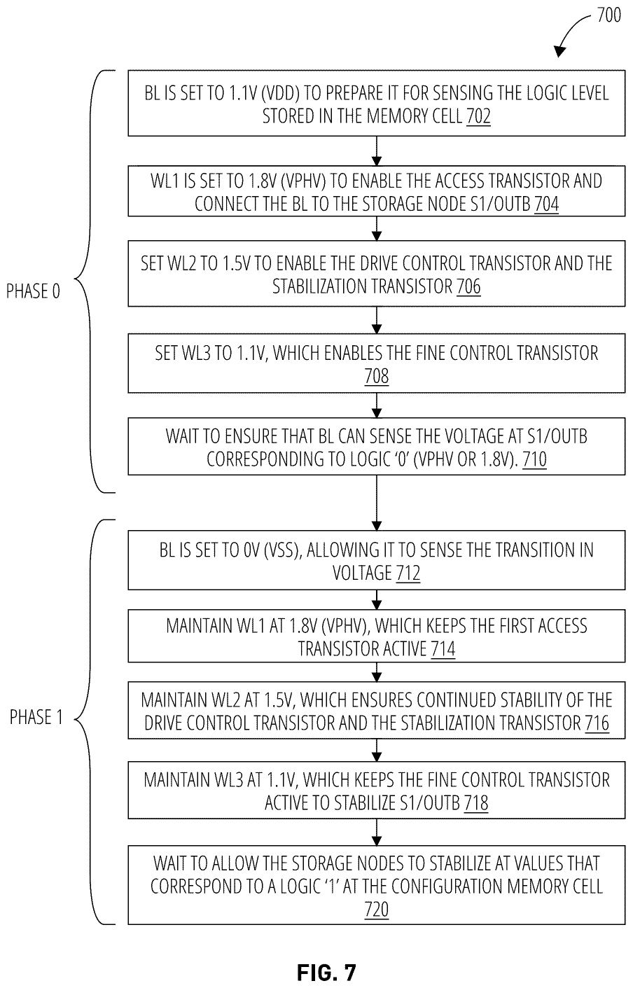

The read/write control line carries the commands that manage the operation of the BL driver 202, WL1 driver 204, WL2 driver 206 and WL3 driver 208. The control line (e.g., commands thereon, without limitation) determines whether the memory system 200 is performing a read or write operation and adjusts driver outputs (e.g., outputs of BL driver 202, WL1 driver 204, WL2 driver 206, or WL3 driver 208, without limitation) accordingly. Outputs of the drivers may cause, directly or indirectly, the states on BL, WL1, WL2, WL3, OUT and OUTB, depicted in the state table of FIG. 7.

In one or more examples, configuration memory cell 210 may support a write operation that respectively includes two write phases: Phase 1 and Phase 2, as discussed below.

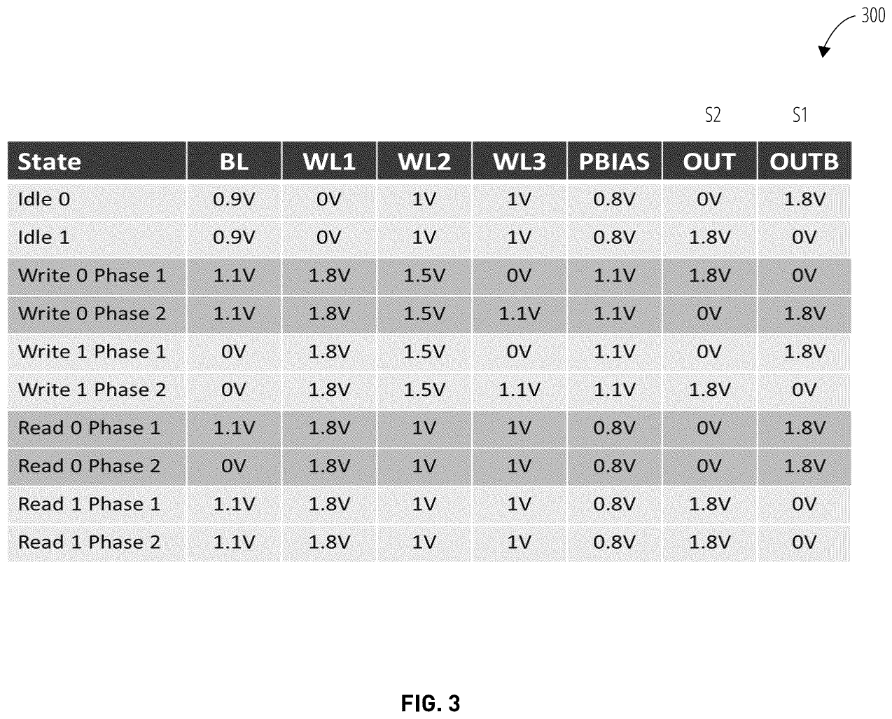

FIG. 3 is a Voltage Bias & State Table 300 depicting operation states of a configuration memory cell or system, such as configuration memory cell 100 or memory system 200, in accordance with one or more examples.

The Voltage Bias & State Table 300 depicted by FIG. 3 provides a detailed breakdown of the voltage levels on various signals in the configuration memory cell (e.g., configuration memory cell 100 or configuration memory cell 210, without limitation) during different operational states. The table 300 demonstrates how the voltages on the Bit Line (BL), Word Line 1 (WL1), Word Line 2 (WL2), Word Line 3 (WL3), and the outputs OUT and OUTB change during Idle, Write, and Read operations, and specifically using a two-phase write process and a two-phase read process. The two-phase processes ensure that the configuration memory cell operates reliably under high-voltage conditions while minimizing the risk of erroneous state changes due to SEUs.

Regarding the columns of the table 300: BL (Bit Line) includes the voltage on BL, which is responsible for transferring data to and from the memory cell during read and write operations. The column WL1 (Word Line 1) includes voltages on WL1, which controls the first access transistor that connects directly to the Bit Line. The column WL2 (Word Line 2) includes voltages on WL2, which controls the drive control transistor that connects the first access transistor to storage node S1. The column WL3 (Word Line 3) includes voltages on WL3, which controls the transistors (e.g., NMOS transistors N1B and N2B of FIG. 1) that connect storage node S1 and output OUT (and optionally storage node S2 if no optional Hi-Res Element is present), respectively, to the pull-down transistors (e.g., NMOS transistors N1A and N2A of FIG. 1, without limitation) that connect to the negative or ground power supply line VSS.

The state column lists example states of the configuration memory cell. For Idle state 0 and Idle state 1: BL is at 0.9V, WL1 is at 0V, WL2 and WL3 are at 1V; PBIAS is at 0.8V; and OUT and OUTB maintain stable logic levels, with OUT at 0V and OUTB at VPHV (1.8V) during Idle 0, and vice versa during Idle 1; and the memory cell holds its state, with no active read or write operation taking place.

In a two-phase access, the word lines WL1, WL2, and WL3 are sequentially activated in access operations on the configuration memory cell. In one or more examples, in a two-phase operation for write 0 or write 1 discussed herein, the circuit preconditions the storage nodes, S1 and S2, by setting them to the opposite state (a preconditioned state) of the desired final value (the written state). This ensures that the correct logic levels can be established more robustly in the subsequent phase. The circuit then finalizes the state by switching the storage nodes from the preconditioned state to the state of the desired final value (the written state).

By having an access transistor controlled by WL1, a drive control transistor controlled by WL2, a stabilization transistor controlled by WL2, and a fine control transistor N1B controlled by WL3, the BL can selectively and directly influence specific storage nodes S1 and S2 during respective phases of the access operation. This direct influence over the storage nodes allows for more precise setting of the desired logic levels.

The preconditioning in the first phase, Phase 0, of a write or read operation makes it easier to achieve the correct final state in Phase 2, reducing the risk of errors due to transient events like SEUs.

Write 0: Phase 0 and Phase 1 relate to write of a logic ‘0’ to the configuration memory cell, which is a two-phase operation. During Phase 1, BL sets the initial condition for the storage nodes, S1 and S2, to a logic ‘1’ at the memory cell, and the NMOS and PMOS transistors of the cross-coupled inverters stabilize the voltage levels at S1/OUTB and S2/OUT at 0V and VPHV, respectively. In Phase 2, BL sets the fully written condition for the storage nodes, S1/OUTB and S2/OUT, to a logic ‘0’ at the memory cell, and the NMOS and PMOS transistors of the cross-coupled inverters stabilize the voltage levels at S1/OUTB and S2/OUT at VPHV and 0, completing the write 0 operation.

In the first phase, Phase 0, BL is set to VDD (1.1V) so that, initially, a logic ‘1’ will be written to the configuration memory cell. WL1 is set to VPHV (1.8V) to enable the first access transistor. WL2 is set to 1.5V to enable the drive control transistor N4 and the stabilization transistor N2B. With all of the first access transistor, the drive control transistor, and the stabilization transistor enabled, BL can coarsely influence S2/OUT and S1/OUTB. Specifically, the PMOS and NMOS transistors in the cross-coupled inverters ensure that S2/OUT reaches VPHV and S1/OUTB reaches 0V in response to BL. WL3 is set to 0V to set the fine control transistor N1B OFF, isolating the secondary control path. This isolation ensures that the state transition at S1/OUTB to 0V occurs gradually and under controlled conditions.

In the second phase of a Write 0 operation, Phase 2, the configuration memory cell transitions from the preconditioned state in Phase 1 to the written state to finalize the writing of a logic ‘0.’

BL remains at VDD (1.1V), continuing to provide the logic ‘1’ precondition required for stable operation and influencing the storage nodes through the cross-coupled inverters. WL1 is set to VPHV (1.8V), enabling the first access transistor. WL2 remains at 1.5V, ensuring that the drive control transistor N4 and the stabilization transistor N2B remain ON. Keeping the access transistor N3, drive control transistor N4, and stabilization transistor N2B all ON, allows the BL to finalize its influence over S1/OUTB and S2/OUT. WL3 is set to 1.1V, turning ON the fine control transistor N1B. This provides fine control over the voltage transition at S1/OUTB, helping to stabilize the logic ‘0’ state being written.

### Write Operation

Write 1: Phase 1 and Phase 2 relate to writing a logic ‘1’ to the configuration memory cell, which is a two-phase operation. During Phase 1, BL sets the initial condition for the storage nodes, S1/OUTB and S2/OUT, to a logic ‘0’ at the memory cell, and the NMOS and PMOS transistors of the cross-coupled inverters stabilize the voltage levels at S1/OUTB and S2/OUT at VPHV and 0V. In Phase 2, BL sets the fully written condition for the storage nodes, S1/OUTB and S2/OUT, to a logic ‘1’ at the memory cell, and the NMOS and PMOS transistors of the cross-coupled inverters stabilize the voltage levels at S1/OUTB and S2/OUT at 0V and VPHV, completing the Write 1 operation.

In the first phase of a Write ‘1’ operation, Phase 0, the configuration memory cell is preconditioned to begin writing a logic ‘1.’ BL is set to 0V (VSS) to provide the initial condition necessary for writing a logic ‘1’ to the memory cell. WL1 is set to 1.8V (VPHV), enabling the access transistor N3. This creates a pathway between the bit line (BL) and the storage node S1/OUTB. WL2 is set to 1.5V, activating the drive control transistor N4 and the stabilization transistor N2B. This configuration allows controlled interaction between the storage nodes and their complementary states. WL3 is set to 0V, keeping the fine control transistor N1B OFF. This isolates the secondary path and prevents interactions with the storage node S1/OUTB during Phase 0. PBIAS is set to 1.1V, ensuring stable operation of the PMOS transistors in the cross-coupled inverters by controlling their gate-source voltage and preventing overvoltage stress. The storage node S2/OUT transitions to 1.8V (VPHV), influenced by the PMOS transistors in the cross-coupled inverters. The storage node S1/OUTB transitions to 0V (VSS), preconditioning the memory cell for the logic ‘1’ state.

In the second phase of a Write ‘1’ operation, Phase 1, the configuration memory cell transitions from the preconditioned state in Phase 0 to finalize the logic ‘1.’ BL remains at 0V (VSS), reinforcing the logic ‘1’ condition being written to the memory cell. WL1 remains at 1.8V (VPHV), keeping the access transistor N3 active and maintaining a portion of the connection between the bit line (BL) and the storage node S1/OUTB. WL2 remains at 1.5V, ensuring that the drive control transistor N4 remains active to maintain another portion of the connection between BL and storage node S1/OUTB, and ensuring the stabilization transistor N2B remain active to provide stability to the storage nodes. WL3 is raised to 1.1V, activating the fine control transistor N1B. This ensures precise stabilization of the storage node S2/OUT at 0V. PBIAS remains at 1.1V, maintaining stable operation of the PMOS transistors in the cross-coupled inverters and protecting them from voltage stress. The storage node S2/OUT is pulled to 0V (VSS) by the NMOS transistors in the cross-coupled inverters. The storage node S1/OUTB is pulled to 1.8V (VPHV), finalizing the logic ‘1’ state.

### Read Operations

Read ‘0’: Phase 0 and Phase 1 of a Read 0 operation relate to reading a stored logic ‘0’ from the configuration memory cell, performed in two phases. During Phase 0, BL is preconditioned to sense the storage nodes, and the first access transistor connects BL to the storage node S1/OUTB. The NMOS and PMOS transistors of the cross-coupled inverters maintain the voltage levels at S1/OUTB and S2/OUT at VPHV and 0V, respectively. In Phase 1, the bit line finalizes sensing the stored state as logic ‘0,’ with the NMOS and PMOS transistors ensuring stable complementary voltage levels at S1/OUTB and S2/OUT, confirming the logic ‘0’ stored in the memory cell.

In the first phase of a Read 0 operation (Phase 0), the memory cell is preconditioned for reading the stored logic ‘0’ by enabling access to the bit line. BL is set to 1.1V (VDD) to prepare it for sensing the voltage level at S2/OUT and S1/OUTB. WL1 is set to 1.8V (VPHV), enabling the first access transistor, connecting BL to S1/OUTB. WL2 is set to 1.5V, keeping the drive control transistor and the stabilization transistor active. This ensures stability of the storage nodes during read operations. WL3 is set to 1V, keeping the fine control transistor N1B active to provide fine-grained control over S2/OUT. PBIAS remains at 0.8V, stabilizing the PMOS transistors in the cross-coupled inverters to prevent excessive voltage stress. S2/OUT: The primary storage node holds 0V (VSS), representing the stored logic ‘0.’ S1/OUTB: The complementary storage node holds 1.8V (VPHV).

In the second phase of a Read 0 operation (Phase 1), the bit line voltage is finalized to ensure reliable sensing of the stored logic ‘0.’ BL is set to 0V (VSS), allowing it to sense the transition in voltage. WL1 remains at 1.8V (VPHV), keeping the first access transistor active. WL2 remains at 1.5V, ensuring continued stability of the drive control transistor and stabilization transistor. WL3 remains at 1V, keeping the fine control transistor N1B active for stabilization. PBIAS remains at 0.8V, stabilizing the PMOS transistors. The voltages at S2/OUT and S1/OUTB remain complementary, with S2/OUT=0V and S1/OUTB=1.8V, confirming the stored logic ‘0.’

Read ‘1’: Phase 0 and Phase 1 of a Read 1 operation relate to reading a stored logic ‘1’ from the configuration memory cell, performed in two phases. During Phase 0, BL is preconditioned to sense the storage nodes, and the first access transistor connects BL to the storage node S1/OUTB. The NMOS and PMOS transistors of the cross-coupled inverters maintain the voltage levels at S1/OUTB and S2/OUT at 0V and VPHV, respectively. In Phase 1, the bit line finalizes sensing the stored state as logic ‘1,’ with the NMOS and PMOS transistors ensuring stable complementary voltage levels at S1/OUTB and S2/OUT, confirming the logic ‘1’ stored in the memory cell.

In the first phase of a Read 1 operation (Phase 0), the memory cell is preconditioned for reading the stored logic ‘1.’ BL is set to 1.1V (VDD) to prepare it for sensing. WL1 is set to 1.8V (VPHV), enabling the first access transistor. WL2 is set to 1.5V, activating the drive control transistor N4 and the stabilization transistor N2B to stabilize the storage nodes. WL3 is set to 1V, keeping the fine control transistor N1B active to stabilize the complementary node. PBIAS remains at 0.8V, ensuring proper operation of the PMOS transistors in the cross-coupled inverters. S2/OUT: The primary storage node holds 1.8V (VPHV), representing the stored logic ‘1.’ S1/OUTB: The complementary storage node holds 0V (VSS).

In the second phase of a Read 1 operation (Phase 1), the bit line voltage is finalized to ensure reliable sensing of the stored logic ‘1.’ BL remains at 1.1V, reinforcing the sensing of the stored logic ‘1.’ WL1 remains at 1.8V, keeping the first access transistor active. WL2 remains at 1.5V, ensuring continued stability of the drive control transistor N4 and stabilization transistor N2B. WL3 remains at 1V, keeping the fine control transistor N1B active for stabilization. PBIAS remains at 0.8V, maintaining stable operation of the PMOS transistors. The voltages at S2/OUT and S1/OUTB remain complementary, with S2/OUT=1.8V and S1/OUTB =0V, confirming the stored logic ‘1.’

In one or more examples, a write and a read, whether a 0 or a 1, respectively include two phases, and each such phase occurs over a single clock cycle. Thus, a write to, and read from, a configuration memory cell 100 occurs over two clock cycles.

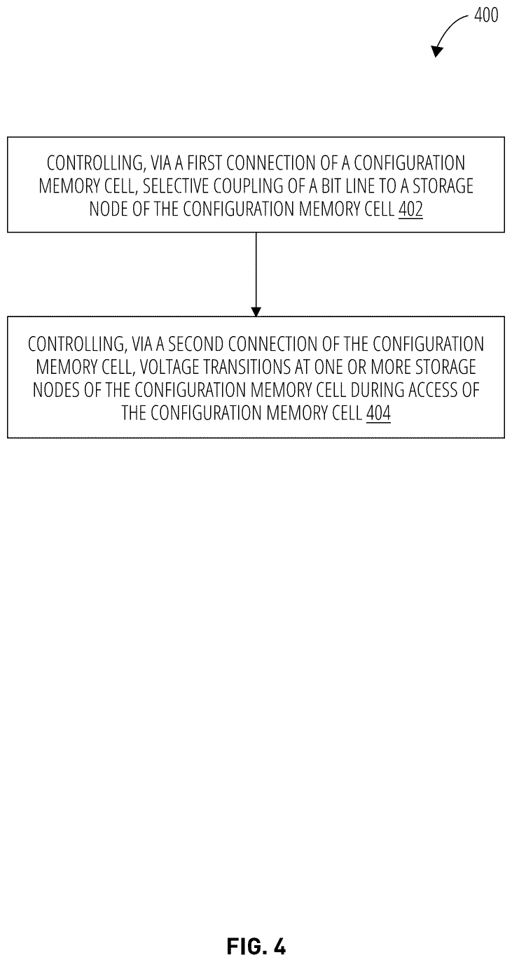

FIG. 4 is a flow diagram depicting example process 400 to control a configuration memory cell such as configuration memory cell 100 or configuration memory cell 210, without limitation, in accordance with one or more examples.

Although the example process 500 depicts a particular sequence of operations, the sequence may be altered without departing from the scope of the present disclosure. For example, some of the operations depicted may be performed in parallel or in a different sequence that does not materially affect the function of the process 500. In other examples, different components of an example device or system that implements the process 500 may perform functions at substantially the same time or in a specific sequence. In one or more examples, some or a totality of operations of process 700 may be performed by a memory system 200 or system incorporating a configuration memory cell 100, more generally.

In one or more examples, some or a totality of operations of process 400 may be performed by a logic circuit cooperatively with one or more drivers of BL, WL1, WL2, and WL3, discussed herein. As non-limiting examples, logic circuit may be integrated with a controller (e.g., of a microcontroller, microprocessor, DSP, or other processor, without limitation) that issues read write commands configured to instruct drivers of BL, WL1, WL2, and WL3 in accordance with some or a totality of operations of process 500. Additionally or alternatively, multiple logic circuits may be integrated with respective drivers of BL, WL1, WL2, and WL3 to cause the drivers to operate in accordance with some or a totality of operations of process 400.

According to one or more examples, process 400 may include, at operation 402, controlling, via a first connection point of a configuration memory cell, selective coupling of a bit line to a storage node of the configuration memory cell. In various examples, process 400 may activate a word line that controls an access transistor (e.g., access transistor N3, without limitation) for switchably coupling the storage node (e.g., storage node S1/OUTB, without limitation) to a bit line (e.g., bit line BL, without limitation). In various examples, process 400 may modulate the drive strength of the access transistor by modulating the respective voltage levels of one or both of WL1 or WL2.

According to one or more examples, process 400 may include, at operation 404, controlling, via a second connection point of the configuration memory cell, voltage transitions at one or more storage nodes of the configuration memory cell during access of the configuration memory cell. In various examples, process 400 may modulate the voltage level of WL2 to control voltage transitions at storage node (e.g., storage node S1/OUTB). For example, during write operations, WL2 modules gate voltage, and therefore current flow, at drive control transistor N4 to ensure that the voltage at S1/OUTB transitions to its final value without overshoot, undershoot, or unintended fluctuations. Further, during read operations, WL2 modulates the gate voltage, and therefore current flow, at drive control transistor N4 to prevent transient disturbances that could disrupt the stored state. In various examples, WL2 also controls the stabilization transistor N2B, which is connected to S2/OUT. Via adjustment of WL2, stabilization transistor N2B ensures that the complementary storage node (S2/OUT) transitions or holds its state as needed, indirectly stabilizing the overall behavior of the cross-coupled inverters.

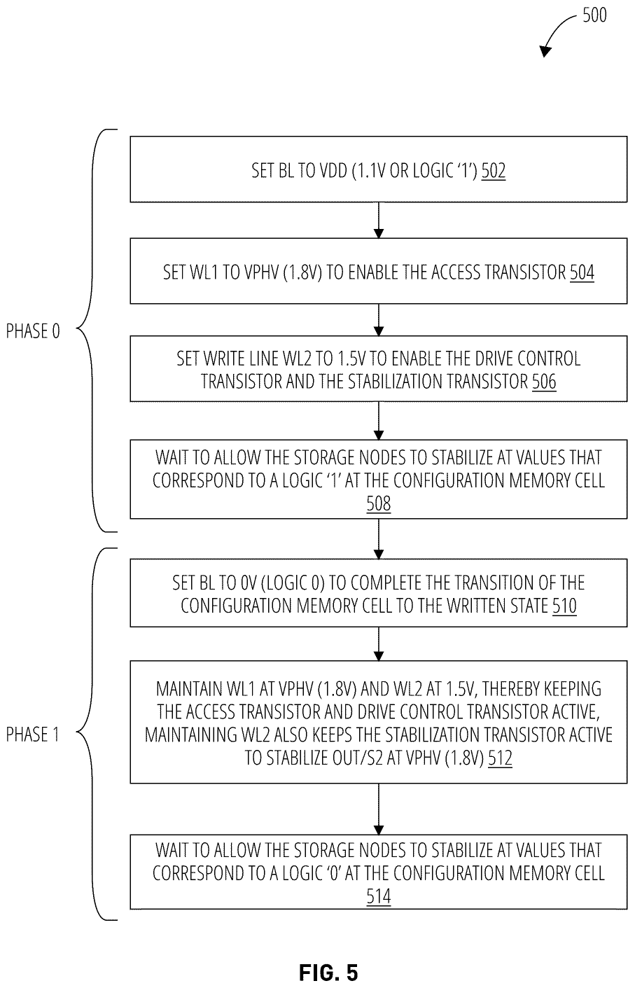

FIG. 5 is a flow diagram depicting an example process 500 for a two-phase write ‘0’ to an example configuration memory cell discussed herein (e.g., configuration memory cell 100, configuration memory cell 210, without limitation), in accordance with one or more examples.

Although the example process 500 depicts a particular sequence of operations, the sequence may be altered without departing from the scope of the present disclosure. For example, some of the operations depicted may be performed in parallel or in a different sequence that does not materially affect the function of the process 500. In other examples, different components of an example device or system that implements the process 500 may perform functions at substantially the same time or in a specific sequence. In one or more examples, some or a totality of operations of process 700 may be performed by a memory system 200 or system incorporating a configuration memory cell 100, more generally.

In one or more examples, some or a totality of operations of process 500 may be performed by a logic circuit cooperatively with one or more drivers of BL, WL1, WL2, and WL3, discussed herein. As non-limiting examples, such as logic circuit may be integrated with a controller (e.g., of a microcontroller, microprocessor, DSP, or other processor, without limitation) that issues read write commands configured to instruct drivers of BL, WL1, WL2, and WL3 in accordance with some or a totality of operations of process 500. Additionally or alternatively, multiple logic circuits may be integrated with respective drivers of BL, WL1, WL2, and WL3 to cause the drivers to operate in accordance with some or a totality of operations of process 500.

According to one or more examples, process 500 may include, at operation 502, setting BL to VDD (1.1V or logic ‘1’). This preconditions the storage nodes and sets up the configuration memory cell in an intermediate state.

According to one or more examples, process 500 may include, at operation 504, setting write line WL1 to VPHV (1.8V) to enable the access transistor (e.g., access transistor N3).

According to one or more examples, process 500 may include, at operation 506, setting write line WL2 to 1.5V to enable the drive control transistor (e.g., drive control transistor N4) and the stabilization transistor N2B. Both the drive control transistors and the stabilization transistor are ON at the same time. Further, both the access transistor N3 and drive control transistor N4 are ON at the same time. When access transistor N3 and drive control transistor N4 are both enabled, this connects BL to the storage node S1/OUTB. Further, when access transistor N3, drive control transistor N4, and stabilization transistor N2B are all active it allows BL to influence S1/OUTB and S2/OUT.

According to one or more examples, process 500 may include, at operation 508, waiting to allow the storage nodes to stabilize at values that correspond to a logic ‘1’ at the configuration memory cell.

According to one or more examples, process 500 may include, at operation 510, setting BL to 0V (logic 0) to complete the transition of the configuration memory cell to the written state.

According to one or more examples, process 500 may include, at operation 512, maintaining WL1 at VPHV (1.8V) and WL2 at 1.5V, thereby keeping the access control transistor and the drive control transistor active and keeping the control transistor active to stabilize S2/OUT at VPHV (1.8V) via the complementary inverter.

According to one or more examples, process 500 may include, at operation 514, waiting to allow the storage nodes to stabilize at values that correspond to a logic ‘0’ at the memory cell.

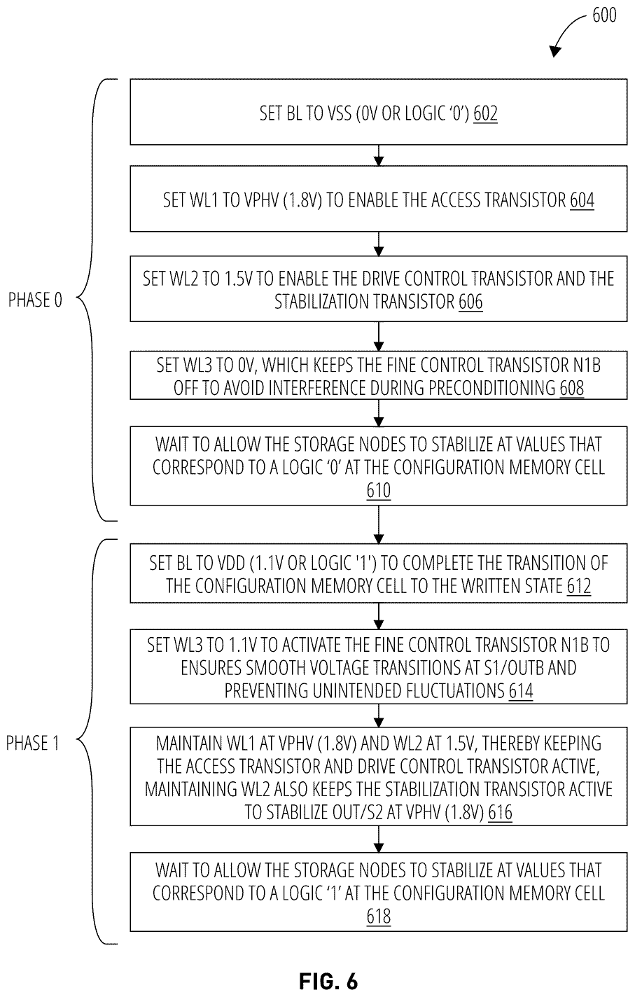

FIG. 6 is a flow diagram depicting an example process 600 for a two-phase write ‘1’ to an example memory cell discussed herein (e.g., configuration memory cell 100 or configuration memory cell 210), in accordance with one or more examples.

Although the example process 600 depicts a particular sequence of operations, the sequence may be altered without departing from the scope of the present disclosure. For example, some of the operations depicted may be performed in parallel or in a different sequence that does not materially affect the function of the process 600. In other examples, different components of an example device or system that implements the process 600 may perform functions at substantially the same time or in a specific sequence.

In one or more examples, some or a totality of operations of process 600 may be performed by a logic circuit cooperatively with one or more drivers of BL, WL1, WL2, and WL3, discussed herein. As non-limiting examples, logic circuit may be integrated with a controller (e.g., of a microcontroller, microprocessor, DSP, or other processor, without limitation) that issues read write commands configured to instruct drivers of BL, WL1, WL2, and WL3 in accordance with some or a totality of operations of process 600. Additionally or alternatively, multiple logic circuits may be integrated with respective drivers of BL, WL1, WL2, and WL3 to cause the drivers to operate in accordance with some or a totality of operations of process 600.

According to one or more examples, process 600 may include, at operation 602, setting BL to 0V (logic 0). This preconditions the storage nodes and sets the memory cell to an intermediate state.

According to one or more examples, process 600 may include, at operation 604, setting WL1 to VPHV (1.8V) to enable the access transistor N3. This at least partially connects the bit line BL to the storage node S1/OUTB.

According to one or more examples, process 600 may include, at operation 606, setting WL2 to 1.5V, which activates both the drive control transistor N4 and the stabilization transistor N2B. Activation of access transistor N3, drive control transistor N4, and stabilization transistor N2B allows the bit line BL to influence S1/OUTB and node S2/OUT.

According to one or more examples, process 600 may include, at operation 608, setting WL3 to 0V, which keeps the fine control transistor N1B OFF to avoid interference during preconditioning.

According to one or more examples, process 600 may include, at operation 610, waiting to allow the storage nodes to stabilize to values that correspond to logic ‘0.’ In this phase, the cross-coupled inverters stabilize S1/OUTB at 0V (VSS) and S2/OUT is driven to VPHV (1.8V), completing the preconditioning.

According to one or more examples, process 600 may include, at operation 612, setting BL to VDD (1.1V) to complete the transition of the memory cell state.

According to one or more examples, process 600 may include, at operation 614, setting WL3 to 1.1V to activate the fine control transistor N1B. This transistor ensures smooth voltage transitions at S1/OUTB, preventing unintended fluctuations.

According to one or more examples, process 600 may include, at operation 616, maintaining WL1 at VPHV (1.8V) and WL2 at 1.5V, which keeps the access transistor and drive control transistor active, and keeps the stabilization transistor active to stabilize S2/OUT at 0V via the complementary inverter.

According to one or more examples, process 600 may include, at operation 618, waiting to allow the storage nodes to stabilize at values that correspond to logic ‘1,’ which is the written state.

FIG. 7 is a flow diagram depicting an example process 700 for a two-phase read ‘0’ from an example configuration memory cell discussed herein (e.g., configuration memory cell 100 or configuration memory cell 210, without limitation), in accordance with one or more examples.

Although the example process 700 depicts a particular sequence of operations, the sequence may be altered without departing from the scope of the present disclosure. For example, some of the operations depicted may be performed in parallel or in a different sequence that does not materially affect the function of the process 700. In other examples, different components of an example device or system that implements the process 700 may perform functions at substantially the same time or in a specific sequence.

In one or more examples, some or a totality of operations of process 700 may be performed by a logic circuit cooperatively with one or more drivers of BL, WL1, WL2, and WL3, discussed herein. As non-limiting examples, such as logic circuit may be integrated with a controller (e.g., of a microcontroller, microprocessor, DSP, or other processor, without limitation) that issues read write commands configured to instruct drivers of BL, WL1, WL2, and WL3 in accordance with some or a totality of operations of process 700. Additionally or alternatively, multiple logic circuits may be integrated with respective drivers of BL, WL1, WL2, and WL3 to cause the drivers to operate in accordance with some or a totality of operations of process 700.

According to one or more examples, process 700 may include, at operation 702, BL is set to 1.1V (VDD) to prepare it for sensing the logic level stored in the memory cell.

According to one or more examples, process 700 may include, at operation 704, WL1 is set to 1.8V (VPHV) to enable the access transistor N3. This connects BL to the storage node S1/OUTB.

According to one or more examples, process 700 may include, at operation 706, WL2 is set to 1.5V, which activates both the drive control transistor N4 and the stabilization transistor NB2. This ensures: Stabilization of S1/OUTB via drive control transistor N4 and stabilization of S2/OUT via stabilization transistor N2B, to ensure no disturbance during sensing.

According to one or more examples, process 700 may include, at operation 708, WL3 is set to 1.1V, activating the fine control transistor N1B to provide additional stability to S1/OUTB.

According to one or more examples, process 700 may include, at operation 710, waiting to ensure that BL can sense the voltage at S1/OUTB, corresponding to logic ‘0’ (VPHV or 1.8V). It is VPHV or 1.8V because OUTB is the commentary output of the cross-coupled inverters 102 and 104.

According to one or more examples, process 700 may include, at operation 712, setting BL to 0V (VSS), allowing it to sense the transition in voltage.

According to one or more examples, process 700 may include, at operation 714, maintaining WL1 at 1.8V (VPHV), which keeps the first access transistor active.

According to one or more examples, process 700 may include, at operation 716, maintaining WL2 at 1.5V, which ensures continued stability of the drive control transistor and the stabilization transistor.

According to one or more examples, process 700 may include, at operation 718, maintaining WL3 at 1.1V, which keeps the fine control transistor active to stabilize S1/OUTB.

According to one or more examples, process 700 may include, at operation 720, waiting to allow the storage nodes to stabilize at values that correspond to a logic ‘1’ at the configuration memory cell.

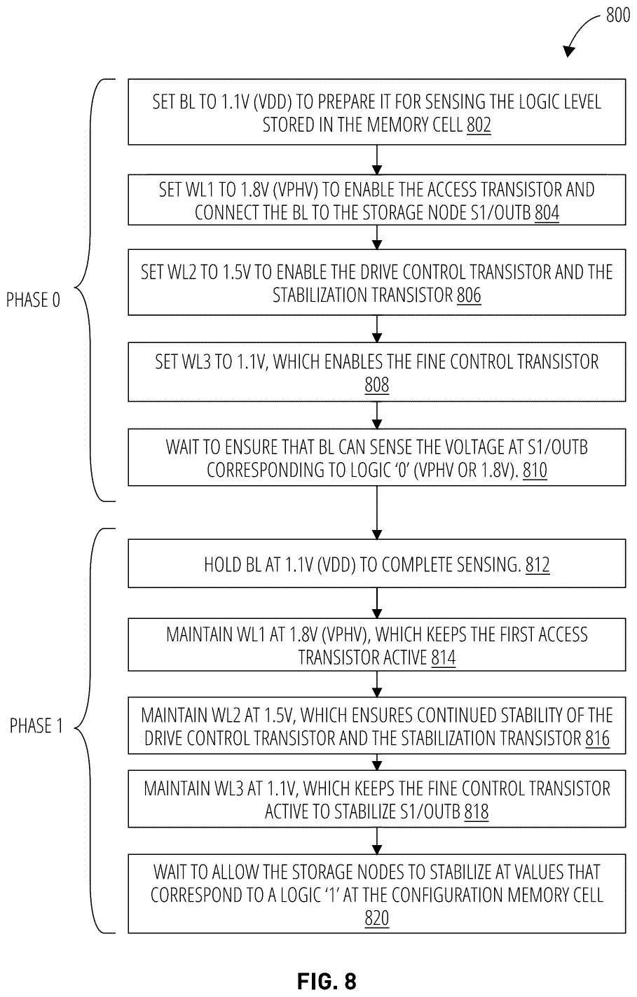

FIG. 8 is a flow diagram depicting an example process 800 for a two-phase read ‘1’ from an example configuration memory cell discussed herein (e.g., configuration memory cell 100 or configuration memory cell 210, without limitation), in accordance with one or more examples.

Although the example process 800 depicts a particular sequence of operations, the sequence may be altered without departing from the scope of the present disclosure. For example, some of the operations depicted may be performed in parallel or in a different sequence that does not materially affect the function of the process 800. In other examples, different components of an example device or system that implements the process 800 may perform functions at substantially the same time or in a specific sequence.

In one or more examples, some or a totality of operations of process 800 may be performed by a logic circuit cooperatively with one or more drivers of BL, WL1, WL2, and WL3, discussed herein. As non-limiting examples, such as logic circuit may be integrated with a controller (e.g., of a microcontroller, microprocessor, DSP, or other processor, without limitation) that issues read write commands configured to instruct drivers of BL, WL1, WL2, and WL3 in accordance with some or a totality of operations of process 800. Additionally or alternatively, multiple logic circuits may be integrated with respective drivers of BL, WL1, WL2, and WL3 to cause the drivers to operate in accordance with some or a totality of operations of process 800.

According to one or more examples, process 800 may include, at operation 802, setting BL to 1.1V (VDD) to prepare it for sensing the logic level stored in the configuration memory cell.

According to one or more examples, process 800 may include, at operation 804, setting WL1 to 1.8V (VPHV) to enable the access transistor and connect the BL to the storage node S1/OUTB.

According to one or more examples, process 800 may include, at operation 806, setting WL2 to 1.5V to enable the drive control transistor and the stabilization transistor. This ensures: stabilization of S1/OUTB via 112 and Stabilization of S2/OUT via 112, ensuring no disturbance during sensing.

According to one or more examples, process 800 may include, at operation 808, setting WL3 to 1.1V, which enables the fine control transistor, which provides additional stability to S1/OUTB.

According to one or more examples, process 800 may include, at operation 810, waiting to ensure that BL can sense the voltage at S1/OUTB corresponding to logic ‘1’ (0V).

According to one or more examples, process 800 may include, at operation 812, holding BL at 1.1V (VDD) to complete sensing.

According to one or more examples, process 800 may include, at operation 814, maintaining WL1 at 1.8V (VPHV), which keeps the first access transistor active.

According to one or more examples, process 800 may include, at operation 816, maintaining WL2 at 1.5V, which ensures continued stability of the drive control transistor and the stabilization transistor.

According to one or more examples, process 800 may include, at operation 818, maintaining WL3 at 1.1V, which keeps the fine control transistor active to stabilize S1/OUTB.

According to one or more examples, process 800 may include, at operation 820, waiting to allow the storage nodes to stabilize at values that correspond to a logic ‘1’ at the configuration memory cell.

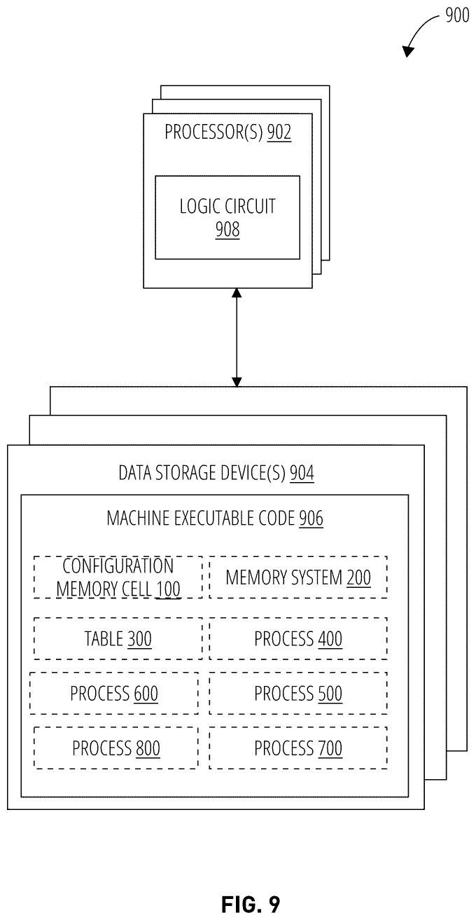

It will be appreciated by those of ordinary skill in the art that functional elements of examples disclosed herein (e.g., functions, operations, acts, processes, or methods) may be implemented in any suitable hardware, software, firmware, or combinations thereof. FIG. 9 illustrates non-limiting examples of implementations of functional elements disclosed herein. In some examples, some or all portions of the functional elements disclosed herein may be performed by hardware capable of carrying out the functional elements.

FIG. 9 is a block diagram of a circuitry 900 that, in some examples, may be used to implement various functions, operations, acts, processes, or methods disclosed herein. The circuitry 900 includes one or more processors 902 (sometimes referred to herein as “processors 902”) operably coupled to one or more data storage devices 904 (sometimes referred to herein as “storage 904”). The storage 904 includes machine executable code 906 stored thereon, and the processors 902 include logic circuit 908. The machine executable code 906 includes information describing functional elements that may be implemented by (e.g., performed by) the logic circuit 908. The logic circuit 908 is adapted to implement (e.g., perform) the functional elements described by the machine executable code 906. The circuitry 900, when executing the functional elements described by the machine executable code 906, should be considered as special purpose hardware for carrying out functional elements disclosed herein. In one or more examples, the processors 902 may perform the functional elements described by the machine executable code 906 sequentially, concurrently (e.g., on one or more different hardware platforms), or in one or more parallel process streams.

When implemented by logic circuit 908 of the processors 902, the machine executable code 906 adapts the processors 902 to be, or perform, some or a totality of features, functions, or operations disclosed herein for one or more of: configuration memory cell 100, of memory system 200 or BL driver 202, WL1 driver 204, WL2 driver 206, WL3 driver 208 or configuration memory cell 210 of memory system 200; the states and bias voltages of table 300; or system 200; process 400, process 500, process 600, process 700, or process 800.

The processors 902 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device (PLD), discrete gate or transistor logic, discrete hardware components, other programmable device, or any combination thereof designed to perform the functions disclosed herein. A general-purpose computer including one or more processors 902, including a general-purpose processor, is considered a special-purpose computer at least while the general-purpose computer executes functional elements corresponding to the machine executable code 906 (e.g., software code, firmware code, configuration data, hardware descriptions, without limitation) related to examples of the present disclosure. It is noted that a general-purpose processor (which may also be referred to herein as a host processor or simply a host) may be a microprocessor, but in the alternative, a general-purpose processor of processors 902 may include any conventional processor, controller, microcontroller, or state-machine. An FPGA or other PLD of the processors 902 may be configured (e.g., programmed, without limitation) with configuration data to perform functions disclosed herein, or, additionally or alternatively, may be capable of being configured or re-configured (e.g., programmable, or re-programmable, without limitation) with configuration data to perform functions disclosed herein. The processors 902 may also be implemented as a combination of computing devices, such as a combination of a DSP and a microprocessor, a plurality of microprocessors, one or more microprocessors in conjunction with a DSP core, or any other such configuration.

In one or more examples, the storage 904 includes volatile data storage (e.g., random-access memory (RAM), static RAM (SRAM), without limitation), non-volatile data storage (e.g., Flash memory, a hard disc drive, a solid state drive, erasable programmable read- only memory (EPROM), without limitation). In some examples the processors 902 and the storage 904 may be implemented into a single device (e.g., a semiconductor device product, a system on chip (SOC), without limitation). In some examples the processors 902 and the storage 904 may be implemented into separate devices.

In one or more examples the machine executable code 906 may include computer-readable instructions (e.g., software code, firmware code). By way of non-limiting example, the computer-readable instructions may be stored by the storage 904, accessed directly by the processors 902, and executed by the processors 902 using at least the logic circuit 908. Also by way of non-limiting example, the computer-readable instructions may be stored on the storage 904, transferred to a memory device (not shown) for execution, and executed by the processors 902 using at least the logic circuit 908. Processors 902 or logic circuit 908 thereof may be coupled to such a memory device or include such a memory device (e.g., a configuration memory cell, without limitation). Accordingly, in some examples, the logic circuit 908 includes electrically configurable logic circuit 908.

In one or more examples the machine executable code 906 may describe hardware (e.g., circuitry) to be implemented in the logic circuit 908 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, VERILOG®, SYSTEMVERILOG™ or very large scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 908 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples the machine executable code 906 may include an HDL, an RTL, a GL description, a mask level description, other hardware description, or any combination thereof.

In examples where the machine executable code 906 includes a hardware description (at any level of abstraction), a system (not shown, but including the storage 904) implements the hardware description described by the machine executable code 906. By way of non-limiting example, the processors 902 may include a programmable logic device (e.g., an FPGA or a PLC, without limitation) and the logic circuit 908 may be electrically controlled (e.g., via configuration data, without limitation) to implement circuitry corresponding to the hardware description into the logic circuit 908. Also by way of non-limiting example, the logic circuit 908 may include hard-wired logic manufactured by a manufacturing system (not shown, but including the storage 904) according to the hardware description of the machine executable code 906.

Regardless of whether the machine executable code 906 includes computer-readable instructions or a hardware description, the logic circuit 908 is adapted to perform the functional elements described by the machine executable code 906 when implementing the functional elements of the machine executable code 906. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, without limitation) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means “some or a totality.” As used herein, the term “each and every” means a “totality.”

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples include:

Example 1: An apparatus, comprising: a configuration memory cell, the configuration memory cell including: a first connection point to control access of one or more storage nodes of the configuration memory cell; a second connection point to manage stability of one or more of the storage nodes of the configuration memory cell during access of the configuration memory cell; and a third connection point to control voltage transitions at one or more storage nodes of the configuration memory cell during access of the configuration memory cell.

Example 2: The apparatus according to Example 1, wherein the configuration memory cell includes a transistor to selectively couple a bit line to one or more of the storage nodes of the configuration memory cell responsive to the first connection point.

Example 3: The apparatus according to Examples 1 and 2, wherein the configuration memory cell includes a transistor to control how strongly a bit line influences one or more storage nodes of the configuration memory cell responsive to the third connection point.

Example 4: The apparatus according to any of Examples 1 to 3, wherein the transistor to exhibit an active drive strength at least partially based on a signal received via the third connection point, and how strongly the bit line influences one or more storage nodes of the configuration memory cell is at least partially based on the active drive strength exhibited by the transistor.

Example 5: The apparatus according to any of Examples 1 to 4, wherein the configuration memory cell includes a further transistor to provide stability to one or more storage nodes of the configuration memory cell by selectively coupling it to a voltage supply responsive to the third connection point.

Example 6: The apparatus according to any of Examples 1 to 5, wherein the further transistor to exhibit an active drive strength at least partially based on a signal received via the third connection point, and responsiveness of one or more storage nodes of the configuration memory cell to the coupled voltage supply at least partially based on the active drive strength exhibited by the further transistor.

Example 7: The apparatus according to any of Examples 1 to 6, wherein the configuration memory cell includes a transistor to provide stability to one or more storage nodes of the configuration memory cell by selectively modulating current flow to or from the storage node, the modulation of current flow at least partially based on a signal received via the second connection point.

Example 8: The apparatus according to any of Examples 1 to 7, comprising: a high-resistance element coupled between a storage node of the one or more storage nodes and an output of the configuration memory cell to enhance single-event upset (SEU) resistance.

Example 9: The apparatus according to any of Examples 1 to 8, wherein the configuration memory cell includes a first inverter and a second inverter cross-coupled between a first node and a second node to store state information represented by complementary voltages at the first node and the second node.

Example 10: The apparatus according to any of Examples 1 to 9, wherein transistors of one or more of the first inverter or second inverter exhibit nonuniform voltage tolerance.

Example 11: A method, comprising: controlling, via a first connection point of a configuration memory cell, selective coupling of a bit line to a storage node of the configuration memory cell; and controlling, via a second connection point of the configuration memory cell, voltage transitions at one or more storage nodes of the configuration memory cell during access of the configuration memory cell.

Example 12: The method according to Example 11, controlling, via a third connection point of a configurations memory cell, stability of one or more of the storage nodes of the configuration memory cell during access of the configuration memory cell.

Example 13: The method according to Examples 11 and 12, comprising: selectively coupling a storage node of the configuration memory cell to a voltage supply to enhance stability of the storage node.

Example 14: The method according to any of Examples 11 to 13, comprising: selectively modulating current flow to or from the storage node to enhance the stability of the storage node.

Example 15: The method according to any of Examples 11 to 14, comprising: adjusting a responsiveness to a coupled voltage of a storage node of the configuration memory cell, the adjusted responsiveness associated with enhanced stability of the storage node.

Example 16: A system, comprising: a configuration memory cell; a bit line driver to drive a bit line coupled to a first connection point of the configuration memory cell; a first write line driver to drive a first write line coupled to a second connection point of the configuration memory cell; a second write line driver to drive a second write line coupled to a third connection point of the configuration memory cell; a third write line driver to drive a third write line coupled to a fourth connection point of the configuration memory cell; and a logic circuit to coordinate the bit line driver, first word line driver, second word line driver, and third write line driver to perform access operation to the configuration memory cell, wherein the logic circuit to dynamically control the configuration memory cell via adjustment of signals generated by the first, second and third write line drivers during access operations to ensure stability and reliable state transitions.

Example 17: The system according to Example 16, wherein the bit line driver, first write line driver, second write line driver, and third write line driver, to generate signals at least partially responsive to instructions received from the logic circuit.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus, comprising:
a configuration memory cell, the configuration memory cell including:
a first connection point to control access of one or more storage nodes of the configuration memory cell;
a second connection point to manage stability of one or more of the storage nodes of the configuration memory cell during access of the configuration memory cell; and
a third connection point to control voltage transitions at one or more storage nodes of the configuration memory cell during access of the configuration memory cell.

2. The apparatus of claim 1, wherein the configuration memory cell includes a transistor to selectively couple a bit line to one or more of the storage nodes of the configuration memory cell responsive to the first connection point.

3. The apparatus of claim 1, wherein the configuration memory cell includes a transistor to control how strongly a bit line influences one or more storage nodes of the configuration memory cell responsive to the third connection point.

4. The apparatus of claim 3, wherein the transistor to exhibit an active drive strength at least partially based on a signal received via the third connection point, and how strongly the bit line influences one or more storage nodes of the configuration memory cell is at least partially based on the active drive strength exhibited by the transistor.

5. The apparatus of claim 3, wherein the configuration memory cell includes a further transistor to provide stability to one or more storage nodes of the configuration memory cell by selectively coupling it to a voltage supply responsive to the third connection point.

6. The apparatus of claim 5, wherein the further transistor to exhibit an active drive strength at least partially based on a signal received via the third connection point, and responsiveness of one or more storage nodes of the configuration memory cell to the coupled voltage supply at least partially based on the active drive strength exhibited by the further transistor.

7. The apparatus of claim 1, wherein the configuration memory cell includes a transistor to provide stability to one or more storage nodes of the configuration memory cell by selectively modulating current flow to or from the one or more storage nodes, the modulation of current flow at least partially based on a signal received via the second connection point.

8. The apparatus of claim 1, comprising:
a high-resistance element coupled between a storage node of the one or more storage nodes and an output of the configuration memory cell to enhance single-event upset (SEU) resistance.

9. The apparatus of claim 1, wherein the configuration memory cell includes a first inverter and a second inverter cross-coupled between a first node and a second node to store state information represented by complementary voltages at the first node and the second node.

10. The apparatus of claim 9, wherein transistors of one or more of the first inverter or second inverter exhibit nonuniform voltage tolerance.

11. A method, comprising:
controlling, via a first connection point of a configuration memory cell, selective coupling of a bit line to a storage node of the configuration memory cell; and
controlling, via a second connection point of the configuration memory cell, voltage transitions at one or more storage nodes of the configuration memory cell during access of the configuration memory cell.

12. The method of claim 11, controlling, via a third connection point of a configurations memory cell, stability of one or more of the storage nodes of the configuration memory cell during access of the configuration memory cell.

13. The method of claim 12, comprising:
selectively coupling a storage node of the configuration memory cell to a voltage supply to enhance stability of the storage node.

14. The method of claim 13, comprising:
selectively modulating current flow to or from the storage node to enhance the stability of the storage node.

15. The method of claim 11, comprising:
adjusting a responsiveness to a coupled voltage of a storage node of the configuration memory cell, the adjusted responsiveness associated with enhanced stability of the storage node.

16. A system, comprising:
a configuration memory cell;
a bit line driver to drive a bit line coupled to a first connection point of the configuration memory cell;
a first write line driver to drive a first write line coupled to a second connection point of the configuration memory cell;
a second write line driver to drive a second write line coupled to a third connection point of the configuration memory cell;
a third write line driver to drive a third write line coupled to a fourth connection of the configuration memory cell; and
a logic circuit to coordinate the bit line driver, first word line driver, second word line driver, and third write line driver to perform access operation to the configuration memory cell, wherein the logic circuit to dynamically control the configuration memory cell via adjustment of signals generated by the first, second and third write line drivers during access operations to ensure stability and reliable state transitions.

17. The system of claim 16, wherein the bit line driver, first write line driver, second write line driver, and third write line driver, to generate signals at least partially responsive to instructions received from the logic circuit.
